(19) United States
(12) Patent Application Publication
(10) Pub. No.: US 2021/0222289 A1
(43) Pub. Date: Jul. 22, 2021

(54) SPUTTERING APPARATUS

(71) Applicant: ULVAC, INC., Chigasaki-shi (JP)

(72) Inventors: Yutaka KOKAZE, Chigasaki-shi (JP); Teruaki IIWAHASHI, Chigasaki-shi (JP); Shunsuke SASAKI, Chigasaki-shi (JP)

(21) Appl. No.: 15/734,889

(22) PCT Filed: Jul. 4, 2019
(86) PCT No.: PCT/JP2019/026613

§ 371 Date: Dec. 3, 2020

(30) Foreign Application Priority Data
Aug. 10, 2018 (JP) 2018-151527

(51) Int. Cl. C23C 14/35; C23C 14/50; C23C 14/34; H01J 37/34

(52) U.S. Cl. CPC C23C 14/35; H01J 37/3414; C23C 14/3407; C23C 14/505

(57) ABSTRACT

A sputtering apparatus includes a plate-shaped regulator that is provided between a target and a substrate, has an opening corresponding to a magnetic circuit, and covers a portion not corresponding to the magnetic circuit. The regulator covers at least a surface area that is greater than or equal to a half of a surface area of the substrate. The opening has a substantially fan-shaped outline. The opening is arranged so as to substantially coincide with the magnetic circuit when viewed in a direction of a rotation axis line of the target, and the rotation axis line of the target and a rotation axis line of the substrate are arranged substantially parallel to each other.

### TECHNICAL FIELD

The present disclosure relates to a sputtering apparatus, and particularly, relates to a technique preferably used for film formation that reduces diagonal components and achieves higher coverage and higher utilization efficiency of a target.

This application claims priority from Japanese Patent Application No. 2018-151527 filed on Aug. 10, 2018, the contents of which are incorporated herein by reference in their entirety.

### BACKGROUND

Conventionally, as a process for manufacturing semiconductor devices, a process of forming a seed layer made of a Cu coating on inner surfaces (an inner wall surface and a bottom surface) of via holes or contact holes having a predetermined aspect ratio is known. As a film formation apparatus used for film formation of the above-described Cu coating, a sputtering apparatus, for example, Patent Document 1 is known. The apparatus includes a vacuum chamber in which a substrate to be processed is disposed so as to face a target, a sputtering gas is introduced into the vacuum chamber, electric power is applied to the target, plasma is generated between the substrate and the target, sputtered particles (Cu radicals or Cu ions) that fly in all directions due to sputtering of the target are adhered to and deposited on the substrate, and a Cu coating is thereby formed on the substrate.

In the technique described in the aforementioned Patent Document 1, directionality of ions is improved by generating a magnetic field between a substrate and a target, and therefore a coating having uniform coverage can be formed on inner wall surfaces of a groove portion.

### PRIOR ART DOCUMENTS

### Patent Documents

[Patent Document 1] Japanese Unexamined Patent Application, First Publication No. 2013-80779

### Summary Problems to be Solved

However, in the technique described in the aforementioned Patent Document 1, there are problems in that, when erosion increases, the number of sputtered particles which are obliquely incident to a substrate to be processed increases, and there is a possibility that coverage becomes degraded; and when erosion decreases, foreign particles are generated due to peeling of a re-deposited coating which is referred to as re-deposition.

Additionally, in the case of reducing a target size in order to reduce erosion, since a lifetime of a target becomes shortened, frequency in maintenance increases in accordance with replacement of the target, and therefore there is a problem in that availability factor of the apparatus is degraded.

The present disclosure was conceived in view of the above-described circumstances and achieves the following objects:

1. Reducing diagonal components of the sputtered particles, reducing asymmetry property, and thereby improving coverage.
2. Improving utilization efficiency of a target.

### Means for Solving the Problems

A sputtering apparatus according to an aspect of the present disclosure includes a cathode and a target attached thereto, the target faces a substrate on which a film is to be formed, the target is sputtered by use of a magnetic circuit provided on a back surface of the target, and thereby a film is formed on the substrate. In the sputtering apparatus, a diameter of the magnetic circuit is set to be smaller than a radius of the target. The sputtering apparatus includes: a substrate rotating unit that rotates the substrate around a rotation axis line of the substrate; a target rotating unit that rotates the target around a rotation axis line of the target; and a plate-shaped regulator that is provided between the target and the substrate, has an opening corresponding to the magnetic circuit, and covers a portion not corresponding to the magnetic circuit. The regulator covers at least a surface area that is greater than or equal to a half of a surface area of the substrate, the opening has a substantially fan-shaped outline, the opening is arranged so as to substantially coincide with the magnetic circuit when viewed in a direction of the rotation axis line of the target, and the rotation axis line of the target and the rotation axis line of the substrate are arranged substantially parallel to each other.

In the sputtering apparatus according to an aspect of the present disclosure, a substantially fan-shaped outline in the shape of the opening may have a center point that is arranged so as to substantially coincide with the rotation axis line of the target when viewed in the rotation axis line of the target.

In the sputtering apparatus according to an aspect of the present disclosure, the rotation axis line of the target may be arranged so as to substantially coincide with the rotation axis line of the substrate when viewed in the rotation axis line of the target.

In the sputtering apparatus according to an aspect of the present disclosure, the rotation axis line of the substrate may be arranged so as to substantially coincide with a center position of a circular arc-shaped edge of the opening having a substantially fan-shaped outline when viewed in a direction of the rotation axis line of the target.

In the sputtering apparatus according to an aspect of the present disclosure, the rotation axis line of the substrate may be arranged so as to substantially coincide with a center of any one of radiuses of the opening having a substantially fan-shaped outline when viewed in a direction of the rotation axis line of the target.

In the sputtering apparatus according to an aspect of the present disclosure, at an outer position in a radial direction with respect to a center point of the opening having a substantially fan-shaped outline, the regulator may have a fan-shaped outline which has a center angle, and the center angle is an obtuse angle so as not to cover the substrate.

In the sputtering apparatus according to an aspect of the present disclosure, the target and the substrate may have diameters that are substantially equal to each other.

In the sputtering apparatus according to an aspect of the present disclosure, a distance between the target and the substrate may be set to be one to three times the diameter of the substrate.

The sputtering apparatus according to an aspect of the present disclosure may further include a magnetic-circuit moving unit that is capable of moving the magnetic circuit in an in-plane direction of the target and in a region smaller than a radius of the target.

A sputtering apparatus according to an aspect of the present disclosure includes a cathode and a target attached thereto, the target faces a substrate on which a film is to be formed, the target is sputtered by use of a magnetic circuit provided on a back surface of the target, and thereby a film is formed on the substrate. In the sputtering apparatus, a diameter of the magnetic circuit is set to be smaller than a radius of the target. The sputtering apparatus includes: a substrate rotating unit that rotates the substrate around a rotation axis line of the substrate; a target rotating unit that rotates the target around a rotation axis line of the target; and a plate-shaped regulator that is provided between the target and the substrate, has an opening corresponding to the magnetic circuit, and covers a portion not corresponding to the magnetic circuit. The regulator covers at least a surface area that is greater than or equal to a half of a surface area of the substrate, the opening has a substantially fan-shaped outline, the opening is arranged so as to substantially coincide with the magnetic circuit when viewed in a direction of the rotation axis line of the target, and the rotation axis line of the target and the rotation axis line of the substrate are arranged substantially parallel to each other.

Consequently, the magnetic circuit becomes smaller than the target radius in size, and the region at which erosion is located at an inclined position with respect to a film formation region of the substrate is reduced. Directions of sputtered particles which are incident to the substrate from the target are regulated by the regulator, and the sputtered particles which are obliquely incident to the substrate from the target are reduced. Asymmetry property is reduced, coverage is improved, and erosion is prevented from being concentrated by rotating the target. The region of the target on which erosion is generated is temporally distributed and expanded. Accordingly, it is possible to prolong a life of the target (lifetime of the target), and it is possible to form a film on the substrate being rotated in a state where utilization efficiency of the target is improved.

Here, it is possible to maintain a state where the incidence angle of the sputtered particles which are incident from the target to the substrate in a diagonal direction is substantially equal to or smaller than the arctangent of the substrate radius and the target-substrate distance with respect to a normal line of the target and the substrate.

In the sputtering apparatus according to an aspect of the present disclosure, a substantially fan-shaped outline in the shape of the opening has a center point that is arranged so as to substantially coincide with the rotation axis line of the target when viewed in the rotation axis line of the target.

Consequently, by reducing the magnetic circuit in size to be smaller than the target radius, the region at which erosion is located at an inclined position with respect to a film formation region of the substrate is reduced. At the same time, the directions in which sputtered particles are incident from the target to the substrate are regulated by the regulator, and sputtered particles which are obliquely incident to the substrate from the target are reduced. Because of this, the asymmetry property of the sputtered particles incident to the substrate is reduced. Therefore, coverage is improved in sputtering. At the same time, erosion is prevented from being concentrated by rotating the target. Furthermore, the region of the target on which erosion is generated is temporally distributed, and therefore the region of the target on which erosion is generated is expanded. Accordingly, it is possible to prolong a life of the target. In addition, it is possible to form a film on the substrate being rotated in a state where utilization efficiency of the target is improved.

Here, it is possible to maintain a state where the incidence angle of the sputtered particles which are incident from the target to the substrate in a diagonal direction is substantially equal to or smaller than the arctangent of the substrate radius and the target-substrate distance with respect to a normal line of the target and the substrate.

In the sputtering apparatus according to an aspect of the present disclosure, the rotation axis line of the target is arranged so as to substantially coincide with the rotation axis line of the substrate when viewed in the rotation axis line of the target.

Therefore, coverage is improved in sputtering. At the same time, erosion is prevented from being concentrated by rotating the target. Furthermore, the region of the target on which erosion is generated is temporally distributed, and therefore the region of the target on which erosion is generated is expanded. Accordingly, it is possible to prolong a life of the target. In addition, it is possible to form a film on the substrate being rotated in a state where utilization efficiency of the target is improved.

Here, it is possible to maintain a state where the incidence angle of the sputtered particles which are incident from the target to the substrate in a diagonal direction is substantially equal to or smaller than the arctangent of the substrate radius and the target-substrate distance with respect to a normal line of the target and the substrate.

In the sputtering apparatus according to an aspect of the present disclosure, the rotation axis line of the substrate is arranged so as to substantially coincide with a center position of a circular arc-shaped edge of the opening having a substantially fan-shaped outline when viewed in a direction of the rotation axis line of the target.

Consequently, the magnetic circuit becomes smaller than the target radius in size, and the region at which erosion is located at an inclined position with respect to a film formation region of the substrate is reduced. Directions in which sputtered particles are incident from the target to the substrate are regulated by the regulator, and sputtered particles which are obliquely incident to the substrate from the target are reduced. Coverage is improved, and erosion is prevented from being concentrated by rotating the target. The region of the target on which erosion is generated is temporally distributed and expanded. It is possible to prolong a life of the target, and it is possible to form a film on the substrate being rotated in a state where utilization efficiency of the target is improved.

Here, the incidence angle of the sputtered particles which are incident from the target to the substrate in a diagonal direction can be in a state of being substantially equal to the arctangent of the substrate radius and the target-substrate distance at a maximum with respect to a normal line of the target and the substrate.

In the sputtering apparatus according to an aspect of the present disclosure, the rotation axis line of the substrate is arranged so as to substantially coincide with a center of any one of radiuses of the opening having a substantially fan-shaped outline when viewed in a direction of the rotation axis line of the target.

Consequently, the magnetic circuit becomes smaller than the target radius in size, and the region at which erosion is located at an inclined position with respect to a film formation region of the substrate is reduced. Directions in which sputtered particles are incident from the target to the substrate are regulated by the regulator, and sputtered particles which are obliquely incident to the substrate from the target are reduced. Coverage is improved, and erosion is prevented from being concentrated by rotating the target. The region of the target on which erosion is generated is temporally distributed and expanded. For this reason, it is possible to prolong a life of the target, and it is possible to form a film on the substrate being rotated in a state where utilization efficiency of the target is improved.

Here, the incidence angle of the sputtered particles which are incident from the target to the substrate in a diagonal direction can be in a state of being substantially equal to the arctangent of a distance between the radius centers of the fan shape of the opening of the regulator at a maximum with respect to a normal line of the target and the substrate. The sputtering apparatus according to an aspect of the present disclosure can solve the aforementioned problems.

In the sputtering apparatus according to an aspect of the present disclosure, at an outer position in the radial direction with respect to a center point of the opening having a substantially fan-shaped outline, the regulator has a fan-shaped outline which has a center angle, and the center angle is an obtuse angle so as not to cover the substrate.

Because of this, the surface area of the regulator is reduced and it is possible to reduce the size of the sputtering apparatus.

In the sputtering apparatus according to an aspect of the present disclosure, the target and the substrate have diameters that are substantially equal to each other.

Accordingly, the region of the rotating target on the outer side in the radial direction on which erosion is not generated is minimized, and it is possible to improve utilization efficiency of the target in a state of prolonging a life of the target.

In the sputtering apparatus according to an aspect of the present disclosure, a distance between the target and the substrate is set to be one to three times the diameter of the substrate.

Consequently, obliquely incident sputtered particles such as long throw sputtering are reduced, coverage is improved, and it is possible to prevent a film formation rate from being reduced.

The sputtering apparatus according to an aspect of the present disclosure includes a magnetic-circuit moving unit that is capable of moving the magnetic circuit in an in-plane direction of the target and in a region smaller than a radius of the target.

Accordingly, erosion is prevented from being concentrated, and life of the target can be further improved.

Furthermore, in the sputtering apparatus according to an aspect of the present disclosure, a magnetic circuit rotating unit that rotates the magnetic circuit around the rotation axis line of the magnetic circuit is provided, the rotation axis line of the magnetic circuit and the rotation axis line of the target are arranged substantially parallel to each other, and the rotation axis line of the magnetic circuit can be arranged to be located inside the opening when viewed in a direction of the rotation axis line of the target.

Moreover, in the sputtering apparatus according to an aspect of the present disclosure, the rotation axis line of the target can be arranged to be located inside the opening when viewed in a direction of the rotation axis line of the target.

Effects of the Present Disclosure

According to the present disclosure, the effects can be obtained in that diagonal components of the sputtered particles are reduced, asymmetry property is reduced, it is possible to improve coverage, and it is possible to improve utilization efficiency of a target.

### BRIEF DESCRIPTION OF THE DRAWINGS

FIG. 1 is a schematic cross-sectional view showing a sputtering apparatus according to a first embodiment of the present disclosure.

FIG. 2 is a schematic plan view showing the sputtering apparatus according to the first embodiment of the present disclosure.

FIG. 3 is a schematic cross-sectional view showing a consumption state of a target of the sputtering apparatus according to the first embodiment of the present disclosure.

FIG. 4 is a schematic cross-sectional view showing a sputtering apparatus according to a second embodiment of the present disclosure.

FIG. 5 is a schematic plan view showing the sputtering apparatus according to the second embodiment of the present disclosure.

FIG. 6 is a schematic plan view showing the sputtering apparatus according to a third embodiment of the present disclosure.

FIG. 7 is a schematic plan view showing the sputtering apparatus according to a fourth embodiment of the present disclosure.

FIG. 8 is a graph showing coverage of Examples of a sputtering apparatus according to the present disclosure.

### EMBODIMENTS FOR CARRYING OUT THE PRESENT DISCLOSURE

Hereinafter, the sputtering apparatus according to a first embodiment of the present disclosure will be described with reference to the drawings.

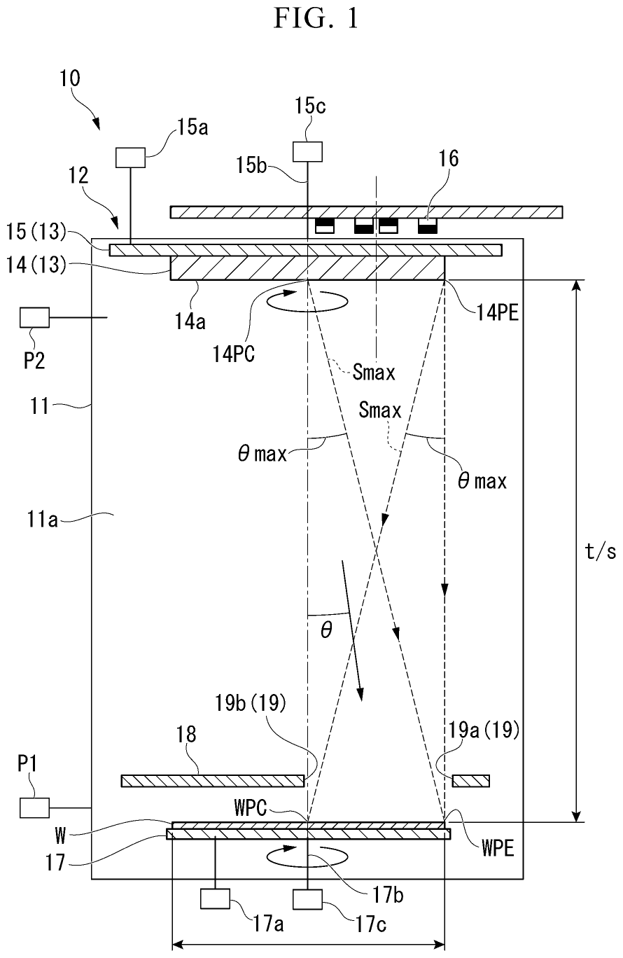

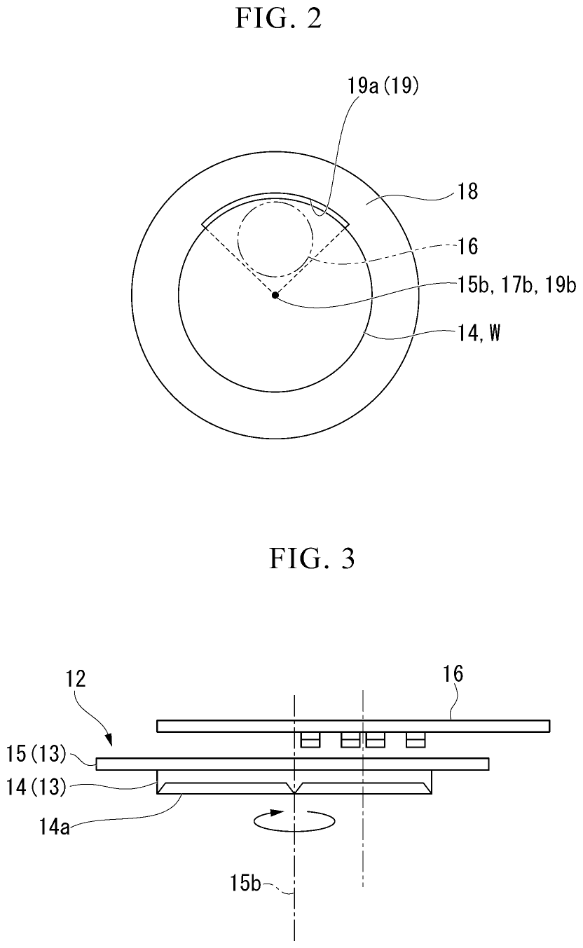

FIG. 1 is a schematic cross-sectional view showing the sputtering apparatus according to the embodiment. FIG. 2 is a schematic plan view showing the sputtering apparatus according to the embodiment. In FIG. 1, reference numeral 10 is a sputtering apparatus.

A substrate W to be processed by the sputtering apparatus 10 according to the embodiment has microscopic holes, steps, or the like which have a high aspect ratio and are formed thereon in advance. For example, in the case of forming a Cu coating on inner surfaces of the holes, the sputtering apparatus 10 according to the embodiment may be used.

The sputtering apparatus 10 according to the embodiment is a magnetron sputtering apparatus, as shown in FIGS. 1 and 2, and includes a vacuum chamber 11 defining a processing chamber 11a. A cathode unit 12 is attached to a ceiling of the vacuum chamber 11.

Note that, in the explanation of the embodiment, as shown in FIG. 1, a direction from the bottom side of the vacuum chamber 11 toward the ceiling side thereof is referred to as “upper” or “upward direction”, and a direction from the ceiling side of the vacuum chamber 11 toward the bottom side thereof is referred to as “lower” or “downward direction”; however, a state where other members of the cathode unit 12 (members constituting the sputtering apparatus 10) are arranged is not limited to this configuration.

The cathode unit 12 is configured to include a target assembly 13 and a magnet unit 16 (magnetic circuit) disposed above the target assembly 13.

The target assembly 13 has a size corresponding to a size of an outline of the substrate W and is configured to include a target 14 that is formed of Cu in a circular plate shape when seen in a plan view by use of a known method and a backing plate 15 that is connected to an upper surface of the target 14 via a bonding member such as indium or the like (not shown in the drawings). The target assembly 13 is configured to be able to cool down the target 14 by causing a cooling medium (cooling water) to flow to an inside of the backing plate 15 when film formation is carried out by sputtering. When output from a sputtering power supply 15a such as a DC power source, a high-frequency power source, or the like is connected to the target 14, and when film formation is carried out, electric power having, for example, a negative electrical potential is supplied to the target 14.

In a state where the backing plate 15 is attached to the target 14, a center of the backing plate 15 is disposed at the upper portion of the vacuum chamber 11, and the backing plate 15 is rotatable along with the target 14 by a target rotating unit 15c around a rotation shaft (rotation axis line) 15b that is a rotation center and extends in a vertical direction.

A lower surface of the target 14 is a sputtering surface 14a. The magnet unit 16 has a configuration that generates a magnetic field in a space under the sputtering surface 14a, captures electrons or the like which were ionized under the sputtering surface 14a when sputtering, and effectively ionizes the sputtered particles which flew from the target 14.

When seen in a plan view, an external outline of the magnet unit 16 is a substantially circular shape, and a diameter of the magnet unit 16 is set to be smaller than a radius of the target 14. However, a shape other than a substantially circular shape can be adopted as an external outline of the magnet unit 16. In this case, the diameter of the magnet unit 16 means the maximum diameter (a size in the horizontal direction).

When seen in a plan view, the magnet unit 16 has a configuration in which a plurality of, for example, double circular-shaped magnets are arranged. In this configuration, the magnets can be arranged such that the polarities of the end portion magnets for each circular line are different from each other between the magnets adjacent to each other.

A stage 17 is disposed at a bottom portion of the vacuum chamber 11 so as to face the sputtering surface 14a of the target 14. The substrate W is held and fixed in position by the stage 17 such that a film formation surface of the substrate W is directed upward. The stage 17 is connected to a high-frequency power source 17a such that bias electrical potential is applied to the stage 17 and the substrate W and has a function of attracting ions of the sputtered particles to the substrate W.

A center of the stage 17 corresponds to the rotation center of a rotation shaft (rotation axis line) 17b extending in the vertical direction. The stage 17 is provided at the lower portion of the vacuum chamber 11 so as to be rotatable together with the substrate W by a substrate rotating unit 17c.

The substrate W and the target 14 are arranged such that both the rotation axis line 17b of the substrate W and the rotation shaft (rotation axis line) 15b of the target 14 extend in the vertical direction so as to be substantially parallel to each other.

In the embodiment, the rotation shaft (rotation axis line) 15b of the target 14 is arranged so as to substantially coincide with the rotation axis line 17b of the substrate W when viewed in the vertical direction parallel to the rotation shaft (rotation axis line) 15b of the target 14.

The target 14 and the substrate W are each set to have a circular shape, and the shapes thereof have substantially the same diameter as each other in size.

The substrate W can be a circular substrate having a diameter of approximately φ300 mm or approximately φ450 mm such as a standard silicon single crystal wafer.

In this case, the distance t/s between the target 14 and the substrate W can be in the range of 400 to 900 mm.

Consequently, the distance t/s between the target 14 and the substrate W can be set in a range of one to three times, or more preferably, 1.5 to 2.5 times the diameter of the substrate W or the target 14.

A vacuuming pipe that is in communication with a vacuum pumping unit P1 configured to include a turbo-molecular pump, a rotary pump, or the like is connected to the bottom portion of the vacuum chamber 11. Moreover, a gas supply pipe that is in communication with a sputtering gas supply unit P2 that supplies a sputtering gas serving as a noble gas such as argon or the like therethrough is connected to a side wall of the vacuum chamber 11, and a mass-flow controller is provided at the gas supply pipe.

The sputtering gas supply unit P2 controls the flow rate of the sputtering gas that is to be introduced into the inside of the processing chamber 11a of the vacuum chamber 11. The inside of the processing chamber 11a of the vacuum chamber 11 is vacuumed at a constant pumping rate by the vacuum pumping unit P1 which will be described later, and the sputtering gas supplied to the inside of the processing chamber 11a is discharged. Because of this, while the sputtering gas is introduced into the processing chamber 11a, during film formation, a pressure (total pressure) inside the processing chamber is maintained substantially constant.

Additionally, a plate-shaped regulator 18 that is provided with an opening 19 allowing the sputtered particles to pass therethrough is disposed between the substrate W and the target 14. The regulator 18 covers the portion except to the opening 19 and regulates an incident region of the sputtered particles with respect to the substrate W to be only the region corresponding to the opening 19.

The regulator 18 is fixed to an adhesion-preventing plate or the like which is disposed inside the side walls of the vacuum chamber 11 with a support member or the like interposed therebetween.

The size of the opening 19 of the regulator 18 corresponds to the size of the magnet unit 16.

The size and the shape of the opening 19 of the regulator 18 are determined so as to cover at least a surface area that is greater than or equal to a half of a surface area of the substrate W.

As shown in FIGS. 1 and 2, the shape of the opening 19 is a substantially fan-shaped outline; when viewed in a direction of a rotation axis line 15b of the target 14 (when seen in a plan view), a center point 19b that is the center of a fan-shaped circular arc 19a is located so as to substantially coincide with the rotation shaft (rotation axis line) 15b of the target 14 and the rotation shaft (rotation axis line) 17b of the substrate W.

The circular arc 19a of the opening 19 is disposed so as to be coincident with the outer edge position of the substrate W or to be outside the outer edge position of the substrate W in a radial-outer direction of the substrate W.

Furthermore, when viewed in a direction of the rotation shaft of the target 14 (rotation axis line) 15b (when seen in a plan view) and when seen in a plan view in a direction which coincides with the rotation shaft (rotation axis line) 15b of the target 14, the opening 19 substantially coincides with the magnet unit 16. In other words, a relationship of the sizes and the shapes of the opening 19 of the regulator 18, the substrate W, the target 14, and the magnet unit 16 is determined such that the outline of the magnet unit 16 having a substantially circular shape becomes largest in a state of being located inside the outline of the opening 19 having a fan-shaped configuration.

Particularly, the center angle of the circular arc 19a of the opening 19 having a fan-shaped configuration is set such that the outline of the magnet unit 16 is located substantially inside the outline of the opening 19 having a fan-shaped configuration when seen in a plan view. Next, the arrangement of the opening 19 of the regulator 18 according to the embodiment, the substrate W, the target 14, and the magnet unit 16, and the trajectory of the sputtered particles will be described.

The regulator 18, the substrate W, the target 14, and the magnet unit 16 are arranged at positions which are substantially parallel to each other, and the magnet unit 16, the target 14, the regulator 18, and the substrate W are arranged in this order from the above.

The substrate W and the target 14 have circular shapes which have substantially the same shape and substantially the same diameter as each other when seen in a plan view.

A diameter of the magnet unit 16 having a circular shape is set to be smaller than a radius of the substrate W and the radius of the target 14.

When seen in a plan view, the regulator 18 covers the entire substrate W except for the portion of the opening 19 and is located such that the magnet unit 16 having a circular shape is located inside the portion of the opening 19.

The rotation shaft (rotation axis line) 17b that is the rotation center of the substrate W and the rotation shaft (rotation axis line) 15b that is the rotation center of the target 14 are arranged in the vertical direction and are located so as to coincide with each other.

The rotation shaft (rotation axis line) 17b of the substrate W, the rotation shaft (rotation axis line) 15b of the target 14, and the center point 19b serving as the center of the fan-shaped circular arc 19a of the fan-shaped outline of the opening 19 provided at the regulator 18 are arranged so as to substantially coincide with each other when seen in a plan view. On the target 14 that rotates around the rotation shaft (rotation axis line) 15b that is the rotation center, only on the region of the target which is one side with respect to the rotation shaft (rotation axis line) 15b, an erosion region is formed by the magnet unit 16 having a circular shape, and the sputtered particles fly out so as to be directed to the substrate W from the erosion region of the target 14.

At this time, of the sputtered particles that flew out from the erosion region of the rotation shaft (rotation axis line) 15b of the target 14, only the sputtered particles that passed through the portion of the opening 19 of the regulator 18 reach the substrate W. Consequently, as shown in FIG. 1, the maximum incidence angle θmax, which means the largest incidence angle of the sputtered particles reaching the substrate W, is represented by the trajectory Smax of the sputtered particles which fly from an outline edge position 14PC that is located on the rotation shaft (rotation axis line) 15b of the magnet unit 16 having a circular shape toward an outline edge position WPE that is located on the fan-shaped circular arc 19a of the opening 19 of the regulator 18 on the opposite side thereof in the horizontal direction.

That is, the angle formed between the trajectory Smax of the sputtered particles and the rotation shaft (rotation axis line) 15b or the rotation shaft (rotation axis line) 17b is the maximum incidence angle θmax.

Accordingly, the incidence angle of the sputtered particles that reach the substrate W is not larger than the maximum incidence angle θmax that is defined by the positional relationship in the horizontal direction between the rotation shaft (rotation axis line) 15b and the outline of the opening 19.

At the same time, of the sputtered particles that flew out from the erosion region on the outer-edge portion side of the target 14, only the sputtered particles that passed through the portion of the opening 19 of the regulator 18 reach the substrate W. Consequently, as shown in FIG. 1, the maximum incidence angle θmax, which means the largest incidence angle of the sputtered particles reaching the substrate W, is represented by the trajectory Smax of the sputtered particles which fly from an outline edge position 14PE that is on the outer-edge portion side of the target 14 of the magnet unit 16 having a circular shape toward an outline edge position WPC that is located on the center point 19b of the opening 19 of the regulator 18 on the opposite side thereof in the horizontal direction.

That is, the angle formed between the trajectory Smax of the sputtered particles and a normal line of the target 14 parallel to the rotation shaft (rotation axis line) 15b is the maximum incidence angle θmax.

Accordingly, the incidence angle θ of the sputtered particles that reach the substrate W is not larger than the maximum incidence angle θmax that is defined by the positional relationship in the horizontal direction between the rotation shaft (rotation axis line) 15b and the outline of the opening 19.

Because of this, since the diameter of the magnet unit 16 is set to be smaller than the radius of the substrate W and the radius of the target 14, it is possible to maintain a state where the incidence angle θ of the sputtered particles which are incident to the substrate W from the target 14 in a diagonal direction is smaller than the arctangent of the distance t/s between the radius of the substrate W and the target 14 with respect to the rotation shaft (rotation axis line) 15b that constitutes a normal line of the target 14 and the substrate W.

FIG. 3 is a schematic cross-sectional view showing a consumption state of a target of the sputtering apparatus according to the embodiment.

Here, since the target 14 rotates around the rotation shaft (rotation axis line) 15b that is a rotation center, the erosion region that is formed only on the region of the target which is one side with respect to the rotation shaft (rotation axis line) 15b rotates and the magnet unit 16 rotates relative to the target 14. Accordingly, as shown in FIG. 3, a state where erosion region of the target 14 rotates is maintained, the target 14 is not locally wasted, and it is possible to prolong a lifetime of the target 14.

Moreover, since the substrate W rotates around the rotation shaft (rotation axis line) 17b that is a rotation center, film formation can be carried out on the entire surface of the substrate W.

Since the substrate W and the target 14 have circular shapes which are substantially the same diameter as each other, it is possible to minimize a region of the target 14 on which erosion is not to be generated; that is, a non-used surface area which is not used for sputtering.

In the embodiment, the magnet unit 16 is set to be smaller than the radius of the target 14, and therefore a region on which erosion is obliquely located with respect to a film formation region of the substrate W defined by the opening 19 is reduced. The directions of the sputtered particles which are incident to the substrate W from the target 14 are regulated by the regulator 18, and the sputtered particles which are obliquely incident to the substrate W from the target 14 are reduced. Asymmetry property is reduced, coverage is improved, and erosion is prevented from being concentrated by rotating the target 14. The region of the target 14 on which erosion is generated is temporally distributed and expanded. Accordingly, it is possible to prolong a life of the target (lifetime of the target), and it is possible to form a film by sputtering on the substrate W being rotated in a state where utilization efficiency of the target is improved.

At the same time, the target 14 and the substrate W have diameters that are substantially equal to each other, and the rotation shaft (rotation axis line) 15b of the target 14 coincides with the rotation shaft (rotation axis line) 17b of the substrate W. Accordingly, the region of the rotating target 14 on the outer side in the radial direction on which erosion is not generated is minimized, and it is possible to improve utilization efficiency of the target in a state of prolonging a life of the target.

Particularly, in the embodiment, a cylindrical shield member that is provided at a position at which the shield member covers the periphery of the target 14 and extends downward to reach the regulator 18 may be disposed in the vacuum chamber 11. Consequently, emission of ions of the sputtered particles toward the substrate W may be assisted.

Hereinafter, the sputtering apparatus according to a second embodiment of the present disclosure will be described with reference to the drawings.

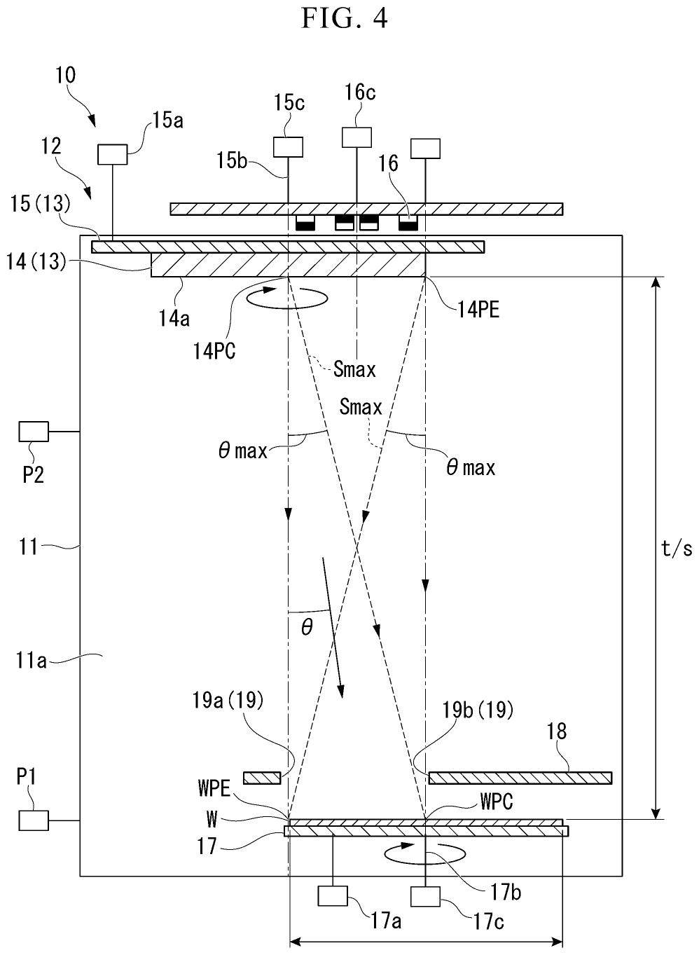

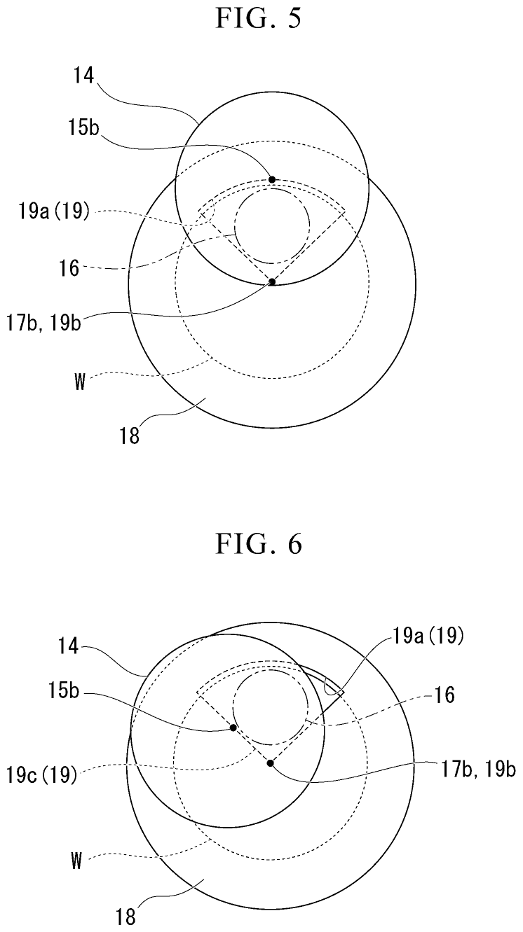

FIG. 4 is a schematic cross-sectional view showing the sputtering apparatus according to the embodiment. FIG. 5 is a schematic plan view showing the sputtering apparatus according to the embodiment. The embodiment is different from the above-mentioned first embodiment in the position of the rotation shaft (rotation axis line) 15b of the target 14. Identical reference numerals are used for the elements which correspond to those of the first embodiment and except for the above, and the explanations thereof are omitted.

In the embodiment, both the rotation shaft (rotation axis line) 15b of the target 14 and the rotation axis line 17b of the substrate W extend in the vertical direction and are arranged so as to be substantially parallel to each other. The rotation shaft (rotation axis line) 15b of the target 14 is disposed at a position different from that of the rotation axis line 17b of the substrate W in the horizontal direction.

Specifically, as shown in FIGS. 4 and 5, the rotation shaft (rotation axis line) 15b of the target 14 is arranged so as to substantially coincide with the midpoint on the circular arc 19a of the opening 19 having a fan-shaped configuration.

The size of the opening 19 of the regulator 18 corresponds to the size of the magnet unit 16.

The size and the shape of the opening 19 of the regulator 18 are determined so as to cover at least a surface area that is greater than or equal to a half of a surface area of the substrate W.

As shown in FIGS. 4 and 5, the opening 19 has a substantially fan-shaped outline, when viewed in a direction of the rotation axis line 15b of the target 14 (when seen in a plan view), the center point 19b serving as the center of the fan-shaped circular arc 19a is arranged so as to substantially coincide with the rotation shaft (rotation axis line) 17b of the substrate W.

The circular arc 19a of the opening 19 is arranged so as to substantially coincide with the outer edge position of the substrate W.

Additionally, when seen in a plan view in a direction which coincides with the rotation shaft (rotation axis line) 15b of the target 14, the opening 19 substantially coincides with the magnet unit 16. In other words, a relationship of the sizes and the shapes of the opening 19 of the regulator 18, the substrate W, the target 14, and the magnet unit 16 is determined such that the outline of the magnet unit 16 having a substantially circular shape becomes largest in a state of being located inside the outline of the opening 19 having a fan-shaped configuration.

Particularly, the center angle of the circular arc 19a of the opening 19 having a fan-shaped configuration is set such that the outline of the magnet unit 16 is located inside the outline of the opening 19 having a fan-shaped configuration.

Next, the arrangement of the opening 19 of the regulator 18 according to the embodiment, the substrate W, the target 14, and the magnet unit 16, and the trajectory of the sputtered particles will be described.

The regulator 18, the substrate W, the target 14, and the magnet unit 16 are arranged at positions which are substantially parallel to each other, and the magnet unit 16, the target 14, the regulator 18, and the substrate W are arranged in this order from the above.

The substrate W and the target 14 have circular shapes which have substantially the same shape and substantially the same diameter as each other when seen in a plan view.

A diameter of the magnet unit 16 having a circular shape is set to be smaller than a radius of the substrate W and a radius of the target 14.

When seen in a plan view, the regulator 18 covers the entire substrate W except for the portion of the opening 19 and is located such that the magnet unit 16 having a circular shape is located inside the portion of the opening 19.

The rotation shaft (rotation axis line) 17b that is the rotation center of the substrate W and the rotation shaft (rotation axis line) 15b that is the rotation center of the target 14 are arranged in the vertical direction and are located so as to be separated from each other at a distance that is equal to the radius of the substrate W or the target 14.

The rotation shaft (rotation axis line) 17b of the substrate W, and the center point 19b serving as the center of the fan-shaped circular arc 19a of the fan-shaped outline of the opening 19 provided at the regulator 18 are arranged so as to substantially coincide with each other when seen in a plan view. The rotation shaft (rotation axis line) 15b of the target 14 and the center point 19b serving as the center of the fan-shaped circular arc 19a of the fan-shaped outline of the opening 19 provided at the regulator 18 are located so as to be separated from each other at a distance that is equal to the radius of the substrate W or the target 14.

On the target 14 that rotates around the rotation shaft (rotation axis line) 15b that is the rotation center, only on the region of the target which is one side with respect to the rotation shaft (rotation axis line) 15b, an erosion region is formed by the magnet unit 16 having a circular shape, and the sputtered particles fly out so as to be directed to the substrate W from the erosion region of the target 14.

At this time, of the sputtered particles that flew out from the erosion region of the rotation shaft (rotation axis line) 15b of the target 14, only the sputtered particles that passed through the portion of the opening 19 of the regulator 18 reach the substrate W. Consequently, as shown in FIG. 4, the maximum incidence angle θmax, which means the largest incidence angle of the sputtered particles reaching the substrate W, is represented by the trajectory Smax of the sputtered particles which fly from an outline edge position 14PC that is located on the rotation shaft (rotation axis line) 15b of the magnet unit 16 having a circular shape toward an outline edge position WPC that is located on the center point 19b of the fan-shaped circular arc 19a of the opening 19 of the regulator 18 on the opposite side thereof in the horizontal direction.

That is, the angle formed between the trajectory Smax of the sputtered particles and the rotation shaft (rotation axis line) 15b or the rotation shaft (rotation axis line) 17b is the maximum incidence angle θmax.

Accordingly, the incidence angle of the sputtered particles that reach the substrate W is not larger than the maximum incidence angle θmax that is defined by the positional relationship in the horizontal direction between the rotation shaft (rotation axis line) 15b and the outline of the opening 19.

At the same time, of the sputtered particles that flew out from the erosion region on the outer-edge portion side of the target 14, only the sputtered particles that passed through the portion of the opening 19 of the regulator 18 reach the substrate W. Consequently, as shown in FIG. 4, the maximum incidence angle θmax, which means the largest incidence angle of the sputtered particles reaching the substrate W, is represented by the trajectory Smax of the sputtered particles which fly from an outline edge position 14PE that is on the outer-edge portion side of the target 14 of the magnet unit 16 having a circular shape toward an outline edge position WPE that is located on the circular arc 19a of the opening 19 of the regulator 18 on the opposite side thereof in the horizontal direction.

That is, the angle formed between the trajectory Smax of the sputtered particles and a normal line of the target 14 parallel to the rotation shaft (rotation axis line) 15b is the maximum incidence angle θmax.

Accordingly, the incidence angle θ of the sputtered particles that reach the substrate W is not larger than the maximum incidence angle θmax that is defined by the positional relationship in the horizontal direction between the rotation shaft (rotation axis line) 15b and the outline of the opening 19.

Because of this, since the diameter of the magnet unit 16 is set to be smaller than the radius of the substrate W and the radius of the target 14, it is possible to maintain a state where the incidence angle θ of the sputtered particles which are incident to the substrate W from the target 14 in a diagonal direction is smaller than the arctangent of the distance t/s between the radius of the substrate W and the target 14 with respect to the rotation shaft (rotation axis line) 15b that constitutes a normal line of the target 14 and the substrate W.

In the embodiment, the magnet unit 16 is set to be smaller than the radius of the target 14, and therefore a region on which erosion is obliquely located with respect to a film formation region of the substrate W defined by the opening 19 is reduced. The directions of the sputtered particles which are incident to the substrate W from the target 14 are regulated by the regulator 18, and the sputtered particles which are obliquely incident to the substrate W from the target 14 are reduced, asymmetry property is reduced, and it is possible to improve coverage.

At the same time, erosion is prevented from being concentrated by rotating the target 14, and the region of the target 14 on which erosion is generated is temporally distributed and expanded. Accordingly, it is possible to prolong a life of the target, and it is possible to form a film by sputtering on the substrate W being rotated in a state where utilization efficiency of the target is improved.

Furthermore, the target 14 and the substrate W have diameters that are substantially equal to each other, and the rotation shaft (rotation axis line) 15b of the target 14 and the rotation shaft (rotation axis line) 17b of the substrate W are separated from each other at a distance that is equal to the radius thereof. Accordingly, the region of the rotating target 14 on the outer side in the radial direction on which erosion is not generated is minimized, and it is possible to improve utilization efficiency of the target in a state of prolonging a life of the target.

In other cases, the embodiment may include a magnetic-circuit moving unit 16c that is capable of moving the magnet unit 16 within a range smaller than a radius of the target 14 in the in-plane direction of the target 14 (horizontal direction), particularly, in the radial direction thereof.

In this case, the magnetic-circuit moving unit 16c can cause the magnet unit 16 to be movable so as not to protrude from the region corresponding to the opening 19 in the horizontal direction. Additionally, as long as the magnetic-circuit moving unit 16c causes the magnet unit 16 to be within the range of the above-mentioned region, a driving method of rotating the magnet unit so as to form a circular shape, oscillating the magnet unit in the range of the above-mentioned region, or the like may be adopted.

Accordingly, the region of the target 14 on which erosion is generated is temporally distributed and expanded, it is possible to prolong a life of the target, and utilization efficiency of the target is improved.

Hereinafter, the sputtering apparatus according to a third embodiment of the present disclosure will be described with reference to the drawings.

FIG. 6 is a schematic plan view showing the sputtering apparatus according to the embodiment. The embodiment is different from the above-mentioned first and second embodiments in the position of the rotation shaft (rotation axis line) 15b of the target 14. Identical reference numerals are used for the elements which correspond to those of the first and second embodiments and except for the above, and the explanations thereof are omitted.

In the embodiment, both the rotation shaft (rotation axis line) 15b of the target 14 and the rotation axis line 17b of the substrate W extend in the vertical direction and are arranged so as to be substantially parallel to each other. The rotation shaft (rotation axis line) 15b of the target 14 is disposed at a position different from that of the rotation axis line 17b of the substrate W in the horizontal direction.

Specifically, as shown in FIG. 6, the rotation shaft (rotation axis line) 15b of the target 14 is arranged so as to substantially coincide with the midpoint on the radius 19c of the opening 19 having a fan-shaped configuration.

The size of the opening 19 of the regulator 18 corresponds to the size of the magnet unit 16.

The size and the shape of the opening 19 of the regulator 18 are determined so as to cover at least a surface area that is greater than or equal to a half of a surface area of the substrate W.

As shown in FIG. 6, the opening 19 has a substantially fan-shaped outline, when viewed in a direction of the rotation axis line 15b of the target 14 (when seen in a plan view), the center point 19b serving as the center of the fan-shaped circular arc 19a is arranged so as to substantially coincide with the rotation shaft (rotation axis line) 17b of the substrate W.

The circular arc 19a of the opening 19 is arranged so as to substantially coincide with the outer edge position of the substrate W or to be outside the outer edge position of the substrate W in a radial-outer direction of the substrate W.

Additionally, when seen in a plan view in a direction which coincides with the rotation shaft (rotation axis line) 15b of the target 14, the opening 19 substantially coincides with the magnet unit 16. In other words, a relationship of the sizes and the shapes of the opening 19 of the regulator 18, the substrate W, the target 14, and the magnet unit 16 is determined such that the outline of the magnet unit 16 having a substantially circular shape becomes largest in a state of being located inside the outline of the opening 19 having a fan-shaped configuration.

Particularly, the center angle of the circular arc 19a of the opening 19 having a fan-shaped configuration is set such that the outline of the magnet unit 16 is located inside the outline of the opening 19 having a fan-shaped configuration.

Next, the arrangement of the opening 19 of the regulator 18 according to the embodiment, the substrate W, the target 14, and the magnet unit 16, and the trajectory of the sputtered particles will be described.

The regulator 18, the substrate W, the target 14, and the magnet unit 16 are arranged at positions which are substantially parallel to each other, and the magnet unit 16, the target 14, the regulator 18, and the substrate W are arranged in this order from the above.

The substrate W and the target 14 have circular shapes which have substantially the same shape and substantially the same diameter as each other when seen in a plan view.

A diameter of the magnet unit 16 having a circular shape is set to be smaller than the radius of the substrate W and the radius of the target 14.

When seen in a plan view, the regulator 18 covers the entire substrate W except for the portion of the opening 19 and is located such that the magnet unit 16 having a circular shape is located inside the portion of the opening 19.

The rotation shaft (rotation axis line) 17b that is the rotation center of the substrate W and the rotation shaft (rotation axis line) 15b that is the rotation center of the target 14 are arranged in the vertical direction and are located so as to be separated from each other at a distance that is approximately half of the radius of the substrate W or the target 14 or is slightly larger than half of the radius of the substrate W or the target 14.

The rotation shaft (rotation axis line) 15b of the target 14 and the center point 19b serving as the center of the fan-shaped circular arc 19a of the fan-shaped outline of the opening 19 provided at the regulator 18 are arranged so as to be separated from each other at a distance that is approximately half of the radius of the substrate W or the target 14 when seen in a plan view. The rotation shaft (rotation axis line) 17b of the substrate W and the center point 19b serving as the center of the fan-shaped circular arc 19a of the fan-shaped outline of the opening 19 provided at the regulator 18 are located so as to substantially coincide with each other.

On the target 14 that rotates around the rotation shaft (rotation axis line) 15b that is the rotation center, only on the region of the target which is one side with respect to the rotation shaft (rotation axis line) 15b, an erosion region is formed by the magnet unit 16 having a circular shape, and the sputtered particles fly out so as to be directed to the substrate W from the erosion region of the target 14.

At this time, of the sputtered particles that flew out from the erosion region that is close to the rotation shaft (rotation axis line) 15b of the target 14, only the sputtered particles that passed through the portion of the opening 19 of the regulator 18 reach the substrate W. Consequently, the maximum incidence angle θmax, which means the largest incidence angle of the sputtered particles reaching the substrate W, is represented by the trajectory Smax of the sputtered particles which fly from an outline edge position that is at a position close to the rotation shaft (rotation axis line) 15b of the magnet unit 16 having a circular shape toward an outline edge position of the opening 19 of the regulator 18 which is at a position far from the rotation shaft (rotation axis line) 15b of the magnet unit 16 having a circular shape on the opposite side thereof in the horizontal direction.

That is, the angle formed between the trajectory Smax of the sputtered particles and the rotation shaft (rotation axis line) 15b or the rotation shaft (rotation axis line) 17b is approximately the maximum incidence angle θmax.

Accordingly, the incidence angle of the sputtered particles that reach the substrate W is not larger than the maximum incidence angle θmax that is defined by the positional relationship in the horizontal direction between the rotation shaft (rotation axis line) 15b and the outline of the opening 19.

At the same time, of the sputtered particles that flew out from the erosion region on the outer-edge portion side of the target 14, only the sputtered particles that passed through the portion of the opening 19 of the regulator 18 reach the substrate W. Consequently, the maximum incidence angle θmax, which means the largest incidence angle of the sputtered particles reaching the substrate W, is represented by the trajectory Smax of the sputtered particles which fly toward an outline edge position of the opening 19 of the regulator 18 which is at a position close to the rotation shaft (rotation axis line) 15b of the target 14 of the magnet unit 16 having a circular shape on the opposite side thereof in the horizontal direction.

That is, the angle formed between the trajectory Smax of the sputtered particles and a normal line of the target 14 parallel to the rotation shaft (rotation axis line) 15b is approximately the maximum incidence angle θmax.

Accordingly, the incidence angle of the sputtered particles that reach the substrate W is not larger than the maximum incidence angle θmax that is defined by the positional relationship in the horizontal direction between the rotation shaft (rotation axis line) 15b and the outline of the opening 19.

Because of this, since the diameter of the magnet unit 16 is set to be smaller than the radius of the substrate W and the radius of the target 14, it is possible to maintain a state where the incidence angle θ of the sputtered particles which are incident to the substrate W from the target 14 in a diagonal direction is smaller than the arctangent of the distance t/s between the radius of the substrate W and the target 14 with respect to the rotation shaft (rotation axis line) 15b that constitutes a normal line of the target 14 and the substrate W.

In the embodiment, the magnet unit 16 is set to be smaller than the radius of the target 14, and therefore a region on which erosion is obliquely located with respect to a film formation region of the substrate W defined by the opening 19 is reduced. The directions of the sputtered particles which are incident to the substrate W from the target 14 are regulated by the regulator 18, and the sputtered particles which are obliquely incident to the substrate W from the target 14 are reduced, asymmetry property is reduced, and it is possible to improve coverage.

At the same time, erosion is prevented from being concentrated by rotating the target 14, and the region of the target 14 on which erosion is generated is temporally distributed and expanded. Accordingly, it is possible to prolong a life of the target, and it is possible to form a film by sputtering on the substrate W being rotated in a state where utilization efficiency of the target is improved.

Furthermore, the target 14 and the substrate W have diameters that are substantially equal to each other, and the rotation shaft (rotation axis line) 15b of the target 14 and the rotation shaft (rotation axis line) 17b of the substrate W are separated from each other at a distance that is equal to a half of the radius thereof. Accordingly, the region of the rotating target 14 on the outer side in the radial direction on which erosion is not generated is minimized, and it is possible to improve utilization efficiency of the target in a state of prolonging a life of the target.

Hereinafter, the sputtering apparatus according to a fourth embodiment of the present disclosure will be described with reference to the drawings.

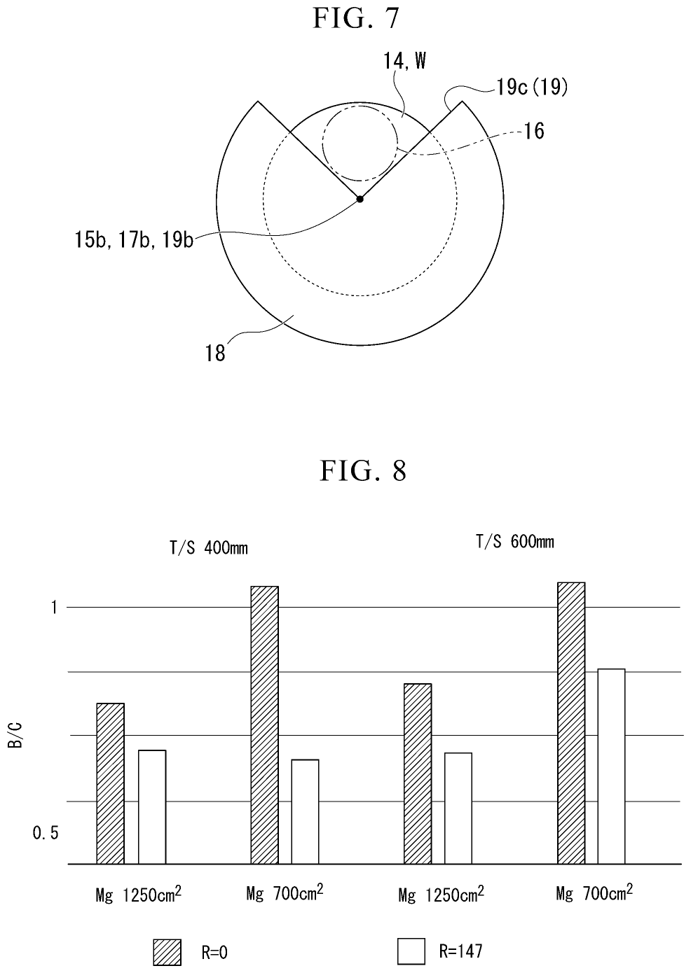

FIG. 7 is a schematic plan view showing the sputtering apparatus according to the embodiment. The embodiment is different from the above-mentioned first to third embodiments in the shape of the regulator 18. Identical reference numerals are used for the elements which correspond to those of the aforementioned first to third embodiments and except for the above, and the explanations thereof are omitted.

In the embodiment, at an outer position in the radial-outer direction with respect to the center point 19b of the opening 19 having a substantially fan-shaped outline, the regulator 18 is formed so as not to cover the substrate W, and the outline of the regulator 18 has a fan-shaped outline having a center angle which is an obtuse angle.

Even in the embodiment, the rotation shaft (rotation axis line) 15b of the target 14 is arranged so as to substantially coincide with the rotation axis line 17b of the substrate W when viewed in the vertical direction parallel to the rotation shaft (rotation axis line) 15b of the target 14.

At this time, of the sputtered particles that flew out from the erosion region near the rotation shaft (rotation axis line) 15b of the target 14, only the sputtered particles that passed through the portion of the opening 19 of the regulator 18 reach the substrate W. Consequently, in a manner similar to the first embodiment shown in FIG. 1, the maximum incidence angle θmax, which means the largest incidence angle of the sputtered particles reaching the substrate W, is represented by the trajectory Smax of the sputtered particles which fly from an outline edge position 14PC that is located on the rotation shaft (rotation axis line) 15b of the magnet unit 16 having a circular shape toward an outline edge position WPE that is close to the outer-edge portion of the substrate W on the opposite side thereof in the horizontal direction.

That is, the angle formed between the trajectory Smax of the sputtered particles and the rotation shaft (rotation axis line) 15b or the rotation shaft (rotation axis line) 17b is the maximum incidence angle θmax.

Accordingly, the incidence angle of the sputtered particles that reach the substrate W is not larger than the maximum incidence angle θmax that is defined by the positional relationship in the horizontal direction between the rotation shaft (rotation axis line) 15b and the outline of the opening 19.

At the same time, of the sputtered particles that flew out from the erosion region on the outer-edge portion side of the target 14, only the sputtered particles that passed through the portion of the opening 19 of the regulator 18 reach the substrate W. Consequently, in a manner similar to the first embodiment shown in FIG. 1, the maximum incidence angle θmax, which means the largest incidence angle of the sputtered particles reaching the substrate W, is represented by the trajectory Smax of the sputtered particles which fly from an outline edge position 14PE that is on the outer-edge portion side of the target 14 of the magnet unit 16 having a circular shape toward the position of the rotation shaft (rotation axis line) 15b of the substrate W on the opposite side thereof in the horizontal direction.

That is, the angle formed between the trajectory Smax of the sputtered particles and a normal line of the target 14 parallel to the rotation shaft (rotation axis line) 15b is the maximum incidence angle θmax.

Accordingly, the incidence angle θ of the sputtered particles that reach the substrate W is not larger than the maximum incidence angle θmax that is defined by the positional relationship in the horizontal direction between the rotation shaft (rotation axis line) 15b and the outer edge outline of the substrate W.

Therefore, a diameter of the magnet unit 16 is set to be smaller than the radius of the substrate W and the radius of the target 14. Because of this, it is possible to maintain a state where the incidence angle θ of the sputtered particles which are incident to the substrate W from the target 14 in a diagonal direction is smaller than the arctangent of the distance t/s between the radius of the substrate W and the target 14 with respect to the rotation shaft (rotation axis line) 15b that constitutes a normal line of the target 14 and the substrate W.

In other cases, in each of the aforementioned embodiments, a collimator that is provided with a plurality of through holes that allow the sputtered particles to pass therethrough may be disposed between the substrate W and the target 14. Not only by the opening 19 of the regulator 18 but also by this case, the incidence angle of the sputtered particles toward the substrate W can be regulated in a predetermined angle range. As a result, oblique incidence of the sputtered particles to the edge of the substrate W is prevented from being generated.

A plate thickness of a collimator can be set to be in, for example, the range of 30 mm to 200 mm. The collimator may be fixed on an inner surface of the adhesion-preventing plate disposed inside the side wall of the vacuum chamber 11 with a support member interposed therebetween. As the adhesion-preventing plate is connected to the ground, the collimator is maintained to have the ground potential. In other cases, another adhesion-preventing plate may also be disposed under the collimator.

Here, as a result of disposing the collimator, oblique incidence of the sputtered particles to the edge of the substrate W is prevented and coverage can further be improved.

Additionally, a configuration can also be adopted by combination of the configurations shown in each of the aforementioned embodiments.

### EXAMPLES

Hereinafter, Examples according to the present disclosure will be described.

### Experimental Example 1

As a specific example of the present disclosure, as shown in FIGS. 1 and 2, the sputtering apparatus 10 is used in which the rotation shaft (rotation axis line) 15b of the target 14, the rotation shaft (rotation axis line) 17b of the substrate W, and the center point 19b of the opening 19 are arranged so as to substantially coincide with each other when viewed in the vertical direction parallel to the rotation shaft (rotation axis line) 15b of the target 14. Sputtering film formation was carried out under the variation of the distance t/s between the target 14 and the substrate W and the surface area Mg of the magnetic circuit 16.

The conditions of the processing in this case are as follows.

Size of the target 14 and size of the substrate W; φ300 mm

Surface area Mg of the magnetic circuit 16 (corresponding to a surface area of erosion); up to 700 cm² (φ300 mm), up to 1250 cm² (φ400 mm)

Center angle of the opening 19 of the regulator 18; 120°

Distance t/s between the target 14 and the substrate W; 400 mm, 600 mm

Material of the target 14; Cu

Flow rate of Ar; 20 sccm when plasma is generated; 0 sccm during film formation

Cathode power; DC 20 kW

Stage Bias power; 300 W

Stage temperature; −20° C.

Target film thickness; 43 nm

After the film formation was carried out, coverage B/C was measured.

Measurement of the coverage B/C was carried out by critical dimension SEM.

In addition, distance R from the center of the substrate W of the measurement position of the coverage B/C; 0 mm to 147 mm.

The results are shown in FIG. 8.

According to the above results, it is determined that the coverage B/C was improved by reducing the surface area Mg of the magnetic circuit 16 (corresponding to a surface area of erosion).

For this reason, it is determined that, although the coverage B/C is in a better condition in the case where the t/s is generally longer, even where the t/s is set to be shorter, the coverage B/C was improved in the same range.

### Experimental Example 2

Next, by using the sputtering apparatus 10 that is provided with the target 14 having the size larger than that of Experimental Example 1, sputtering film formation was carried out. Additionally, for comparison, sputtering film formation was carried out by using the sputtering apparatus 10 in which the rotation shaft (rotation axis line) 15b of the target 14 is displaced from the rotation shaft (rotation axis line) 17b of the substrate W toward the circular arc 19a of the opening 19, the target 14 does not rotate, a central axis corresponding to the rotation shaft (rotation axis line) 15b of the target 14 is disposed so as to coincide with the rotation shaft of the magnetic circuit 16.

The conditions of the processing in this case are as follows.

Size of the target 14; φ400 mm

Size of the substrate W; φ300 mm

Surface area Mg of the magnetic circuit 16; 700 cm² (φ300 mm)

Center angle of the opening 19 of the regulator 18; 120° Distance t/s between the target 14 and the substrate W; 600 mm Distance between the rotation center axis of the magnetic circuit 16 and the rotation shaft of the substrate W; 75 mm (the rotation shaft of the magnetic circuit 16 is located at the center of the regulator 18 of the opening 19)

Material of the target 14; Cu

Flow rate of Ar; 20 sccm when plasma is generated; 0 sccm during film formation

Cathode power; DC 20 kW

Stage Bias power; 300 W

Stage temperature; −20° C.

Target film thickness; 43 nm According to the above results, even where the magnetic circuit 16 is small, without rotation of the target 14, when the central axis of the target 14 coincides with the rotation shaft of the magnetic circuit 16, the surface area on which erosion is generated was equal to the surface area of the magnetic circuit 16 and was 700 cm² (φ300 mm).

In contrast, in the case of rotating the target 14 and adopting the arrangement in which the rotation shaft (rotation axis line) 15b of the target 14 and the rotation shaft of the magnetic circuit 16 are displaced from each other as shown in FIG. 1, it is possible to cause the region on which erosion is generated to be the entire surface of the target 14, and the surface area of the erosion was 1256 cm² (φ400 mm).

Accordingly, it is determined that, as the surface area of the erosion changes from “up to 1250 cm²” to “700 cm²”, the life of the target is improved at approximately 1.8 times.

### DESCRIPTION OF REFERENCE NUMERALS

10 . . . sputtering apparatus
11 . . . vacuum chamber
11a . . . processing chamber
12 . . . cathode unit
13 . . . target assembly
14 . . . target
14a . . . sputtering surface
15 . . . backing plate
15a . . . sputtering power supply
15b . . . rotation shaft (rotation axis line)
15c . . . target rotating unit
16 . . . magnet unit (magnetic circuit)
16c . . . magnetic-circuit moving unit
17 . . . stage
17a . . . high-frequency power source
17b . . . rotation shaft (rotation axis line)
17c . . . substrate rotating unit
18 . . . regulator
19 . . . opening
19a . . . circular arc
19b . . . center point
19c . . . radius
W . . . substrate

What is claimed is:

1. A sputtering apparatus comprising a cathode and a target attached thereto, the target facing a substrate on which a film is to be formed, the sputtering apparatus sputtering the target by use of a magnetic circuit provided on a back surface of the target, and thereby forming a film on the substrate, wherein
a diameter of the magnetic circuit is set to be smaller than a radius of the target,
the sputtering apparatus comprises:
a substrate rotating unit that rotates the substrate around a rotation axis line of the substrate;
a target rotating unit that rotates the target around a rotation axis line of the target; and
a plate-shaped regulator that is provided between the target and the substrate, has an opening corresponding to the magnetic circuit, and covers a portion not corresponding to the magnetic circuit, wherein
the regulator covers at least a surface area that is greater than or equal to a half of a surface area of the substrate,
the opening has a substantially fan-shaped outline,
the opening is arranged so as to substantially coincide with the magnetic circuit when viewed in a direction of the rotation axis line of the target, and
the rotation axis line of the target and the rotation axis line of the substrate are arranged substantially parallel to each other.

2. The sputtering apparatus according to claim 1, wherein
a substantially fan-shaped outline in a shape of the opening has a center point that is arranged so as to substantially coincide with the rotation axis line of the target when viewed in the rotation axis line of the target.

3. The sputtering apparatus according to claim 1, wherein
the rotation axis line of the target is arranged so as to substantially coincide with the rotation axis line of the substrate when viewed in the rotation axis line of the target.

4. The sputtering apparatus according to claim 1, wherein
the rotation axis line of the substrate is arranged so as to substantially coincide with a center position of a circular arc-shaped edge of the opening having a substantially fan-shaped outline when viewed in a direction of the rotation axis line of the target.

5. The sputtering apparatus according to claim 1, wherein
the rotation axis line of the substrate is arranged so as to substantially coincide with a center of any one of radiuses of the opening having a substantially fan-shaped outline when viewed in a direction of the rotation axis line of the target.

6. The sputtering apparatus according to claim 3, wherein at an outer position in a radial direction with respect to a center point of the opening having a substantially fan-shaped outline, the regulator has a fan-shaped outline which has a center angle, and the center angle is an obtuse angle so as not to cover the substrate.

7. The sputtering apparatus according to claim 1, wherein the target and the substrate have diameters that are substantially equal to each other.

8. The sputtering apparatus according to claim 1, wherein a distance between the target and the substrate is set to be one to three times a diameter of the substrate.

9. The sputtering apparatus according to claim 1, further comprising:
a magnetic-circuit moving unit that is capable of moving the magnetic circuit in an in-plane direction of the target and in a region smaller than a radius of the target.
